(19) United States
(12) Patent Application Publication
(10) Pub. No.: US 2025/0221165 A1
(43) Pub. Date: Jul. 3, 2025

(54) Transparent Display Device

(71) Applicant: LG Display Co., Ltd., Seoul (KR)

(72) Inventors: Seongkwang Kim, Goyang-si (KR); Seongku Lee, Seoul (KR); Kihyung Lee, Yongin-si (KR)

(21) Appl. No.: 18/771,351

(22) Filed: Jul. 12, 2024

(30) Foreign Application Priority Data
Dec. 28, 2023 (KR) 10-2023-0194827

(51) Int. Cl. H10K 59/121; H10K 59/131; H10K 59/35; H10K 71/00

(52) U.S. Cl. CPC H10K 59/1213; H10K 59/1216; H10K 59/131; H10K 59/351; H10K 71/861

(57) ABSTRACT

A transparent display device includes a substrate with a plurality of sub-pixels on the substrate, the substrate including a transmission area and an emission area, a driving transistor in the emission area, the driving transistor including semiconductor layer, an organic light emitting diode connected to the driving transistor, the organic light emitting diode including an anode, and an anode connection line extending from the semiconductor layer of the driving transistor to the transmission area, the anode connection line connected to the anode of the organic light emitting diode. The transparent display device presented herein features an improved aperture ratio and transparency.

### CROSS-REFERENCE TO RELATED APPLICATION

This application claims the priority from Republic of Korea Patent Application No. 10-2023-0194827 filed on Dec. 28, 2023, which is hereby incorporated by reference in its entirety.

### BACKGROUND

### Field

The present disclosure relates to a transparent display device, and more particularly, to a transparent display device in which an aperture ratio and transparency can be improved.

### Description of Related Art

Organic light emitting display devices are self-luminous display devices and do not require a separate light source unlike liquid crystal display devices. Thus, the organic light emitting display devices can be manufactured into a lightweight and thin form. Further, the organic light emitting display devices are not only advantageous in terms of power consumption by low voltage driving, but also has excellent response speed, viewing angle, and contrast ratio.

Attempts have been made to manufacture such an organic light emitting display device as a transparent organic light emitting display device, which is a transparent display device. A pixel area of the transparent organic light emitting display device is divided into an emission area in which an organic light emitting diode emits light to display an image, and a transmission area which transmits external light. Transparency of the transparent organic light emitting display device is secured through the transmission area. Meanwhile, in the pixel area, the emission area and the transmission area are in a trade-off relationship that an increase in the emission area decreases the transmission area and an increase in the transmission area decreases the emission area. Thus, it is difficult to increase an aperture ratio of the emission area. Therefore, research has been continued to increase the aperture ratio of the emission area without reducing the transmission area in the transparent display device.

### SUMMARY

An object to be achieved by the present disclosure is to provide a transparent display device which can be repaired when a malfunction or defect of the sub-pixel is detected.

Another object to be achieved by the present disclosure is to provide a transparent display device in which an aperture ratio and transparency can be improved.

Objects of the present disclosure are not limited to the above-mentioned objects, and other objects, which are not mentioned above, can be clearly understood by those skilled in the art from the following descriptions.

A transparent display device according to one or more embodiments of the present disclosure includes a substrate with a plurality of sub-pixels on the substrate, the substrate including a transmission area and an emission area, a driving transistor in the emission area, the driving transistor including a semiconductor layer, an organic light emitting diode connected to the driving transistor, the organic light emitting diode including an anode, and an anode connection line extending from the semiconductor layer of the driving transistor to the transmission area, the anode connection line connected to the anode of the organic light emitting diode.

Other detailed matters of the embodiments of the present disclosure are included in the detailed description and the drawings.

According to the present disclosure, a repair part is provided to perform a repair when a malfunction or defect of a sub-pixel is detected.

According to the present disclosure, instead of a metal line, an oxide semiconductor layer is used as a line for repair. Also, a repair is performed by irradiating a laser from below a substrate. Thus, it is possible to improve an aperture ratio and transparency.

The effects according to the present disclosure are not limited to the contents exemplified above, and more various effects are included in the present specification.

### BRIEF DESCRIPTION OF DRAWINGS

The above and other embodiments, features and other advantages of the present disclosure will be more clearly understood from the following detailed description taken in conjunction with the accompanying drawings, in which:

FIG. 1 is a block diagram for explaining a transparent display device according to one or more embodiments of the present disclosure;

FIG. 2 is a schematic circuit diagram of a sub-pixel according to one or more embodiments of the present disclosure;

FIG. 3 is a detailed circuit diagram of the sub-pixel according to one or more embodiments of the present disclosure;

FIG. 4 is a plan view of a transparent display device according to a first embodiment of the present disclosure;

FIG. 5 is an enlarged view of a first repair part of FIG. 4 according to the first embodiment of the present disclosure;

FIG. 6A and FIG. 6B are cross-sectional views taken along a line A-A of FIG. 5 according to the first embodiment of the present disclosure;

FIG. 7 is an enlarged view of a second repair part of FIG. 4 according to the first embodiment of the present disclosure;

FIG. 8 is a cross-sectional view taken along a line B-B of FIG. 7 according to the first embodiment of the present disclosure;

FIG. 9 is a plan view of a transparent display device according to a second embodiment of the present disclosure;

FIG. 10 is an enlarged view of a first repair part of FIG. 9 according to the second embodiment of the present disclosure;

FIG. 11 is a cross-sectional view taken along a line X-X′ of FIG. 10 according to the second embodiment of the present disclosure;

FIG. 12A and FIG. 12B are cross-sectional views taken along a line C-C of FIG. 10 according to the second embodiment of the present disclosure;

FIG. 13 is an enlarged view of a second repair part of FIG. 9 according to the second embodiment of the present disclosure; and

FIG. 14 is a cross-sectional view taken along a line D-D of FIG. 13 according to the second embodiment of the present disclosure.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, embodiments of the present disclosure will be described in detail with reference to the drawings.

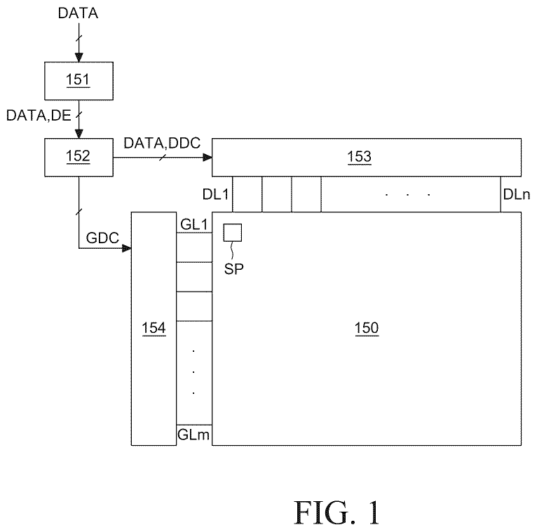

FIG. 1 is a block diagram for explaining a transparent display device according to one or more embodiments of the present disclosure.

Referring to FIG. 1, the transparent display device may include an image processor 151, a timing controller 152, a data driver 153, a scan driver 154, and a display panel 150.

The image processor 151 may output a data enable signal DE together with a data signal DATA supplied from the outside.

Further, for example, the image processor 151 may output one or more of a vertical synchronization signal, a horizontal synchronization signal, and a clock signal in addition to the data enable signal DE.

The timing controller 152 may receive the data enable signal DE or the data signal DATA, together with driving signals including the vertical synchronization signal, the horizontal synchronization signal, the clock signal, etc., from the image processor 151. The timing controller 152 may output a gate timing control signal GDC for controlling operation timing of the scan driver 154 and a data timing control signal DDC for controlling operation timing of the data driver 153 based on the driving signals.

The data driver 153 may sample and latch the data signal DATA received from the timing controller 152 in response to the data timing control signal DDC received from the timing controller 152. Also, the data driver 153 may convert the sampled and latched data signal DATA into a gamma reference voltage. The data driver 153 may output the data signal DATA through data lines DL1 to DLn. The data driver 153 may be configured in the form of an integrated circuit (IC).

The scan driver 154 may output a scan signal in response to the gate timing control signal GDC received from the timing controller 152. The scan driver 154 may output the scan signal through gate lines GL1 to GLm. The scan driver 154 may be configured in the form of an IC or may be mounted on the display panel 150 in a gate-in-panel (GIP) manner.

The display panel 150 may display an image in response to the data signal DATA and the scan signal respectively received from the data driver 153 and the scan driver 154.

The display panel 150 may include a plurality of sub-pixels SP to display an image.

For example, the sub-pixels SP may include a red sub-pixel, a green sub-pixel, and a blue sub-pixel, or may include a white sub-pixel, a red sub-pixel, a green sub-pixel, and a blue sub-pixel. Further, the sub-pixels SP may have one or more different emission areas depending on emission characteristics.

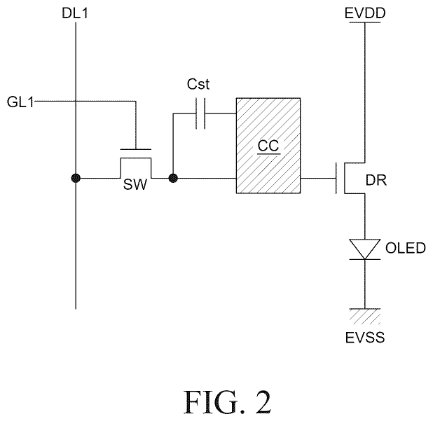

FIG. 2 is a schematic circuit diagram of a sub-pixel according to one or more embodiments of the present disclosure.

Referring to FIG. 2, each sub-pixel may include a switching transistor SW, a driving transistor DR, a capacitor Cst, a compensation circuit CC, and an organic light emitting diode OLED.

The switching transistor SW may perform a switching operation so that a data signal supplied through a data line DL1 is stored in the capacitor Cst as a data voltage in response to a scan signal supplied through a first gate line GL1. The driving transistor DR enables a driving current to flow between a power line EVDD (high-potential voltage) and a cathode power line EVSS (low-potential voltage) based on the data voltage stored in the capacitor Cst. The organic light emitting diode OLED may emit light depending on the driving current generated by the driving transistor DR.

The compensation circuit CC is a circuit added to the sub-pixel and compensates for a threshold voltage of the driving transistor DR. The compensation circuit CC includes one or more transistors. A configuration of the compensation circuit CC may be variously changed depending on an external compensation method and will be described below.

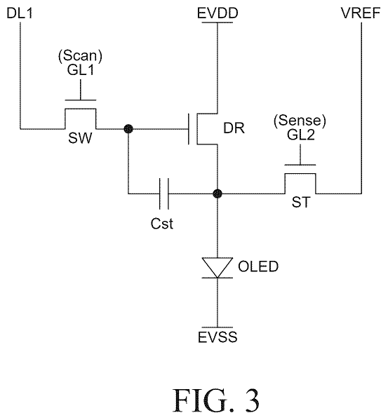

FIG. 3 is a detailed circuit diagram of the sub-pixel according to one or more embodiments of the present disclosure.

Referring to FIG. 3, the compensation circuit CC may include, for example, a sensing transistor ST and a sensing line (or a reference line) VREF.

Herein, the sensing transistor ST may be connected between a source electrode of the driving transistor DR and an anode of the organic light emitting diode OLED (hereinafter, referred to as “sensing node”). The sensing transistor ST may operate to supply an initialization voltage (or sensing voltage) transferred through the sensing line VREF to the sensing node of the driving transistor DR. Also, the sensing transistor ST may operate to sense a voltage or current of the sensing node or sensing line VREF of the driving transistor DR.

A source electrode or drain electrode of the switching transistor SW may be connected to the data line DL1. The other one of the source electrode and the drain electrode of the switching transistor SW may be connected to a gate electrode of the driving transistor DR.

A source electrode or drain electrode of the driving transistor DR may be connected to the power line EVDD. The other one of the source electrode and the drain electrode of the driving transistor DR may be connected to a first electrode, which is the anode, of the organic light emitting diode OLED.

Further, a lower electrode of the capacitor Cst may be connected to the gate electrode of the driving transistor DR, and an upper electrode of the capacitor Cst may be connected to the anode of the organic light emitting diode OLED. The first electrode of the organic light emitting diode OLED may be connected to the other one of the source electrode and the drain electrode of the driving transistor DR. Also, a second electrode, which is a cathode, of the organic light emitting diode OLED may be connected to the second power line EVSS.

A source electrode or drain electrode of the sensing transistor ST may be connected to the sensing line VREF. The other one of the source electrode and the drain electrode of the sensing transistor ST may be connected to the first electrode of the organic light emitting diode OLED corresponding to the sensing node and the other one of the source electrode and the drain electrode of the driving transistor DR.

An operation time of the sensing transistor ST may be similar (or identical) to or different from that of the switching transistor SW depending on an external compensation algorithm (or the configuration of the compensation circuit). For example, a gate electrode of the switching transistor SW may be connected to a first gate line GL1, and a gate electrode of the sensing transistor ST may be connected to a second gate line GL2. Herein, a scan signal Scan may be transmitted to the first gate line GL1 and a sensing signal Sense may be transmitted to the second gate line GL2. As another example, the first gate line GL1 connected to the gate electrode of the switching transistor SW and the second gate line GL2 connected to the gate electrode of the sensing transistor ST may be connected so that they can be commonly shared.

The sensing line VREF may be connected to the data driver. In this case, the data driver may sense the sensing node of the sub-pixel and generate a sensing result in real time or during a non-display period of an image or N period (N is an integer equal to or greater than 1).

Meanwhile, the switching transistor SW and the sensing transistor ST may be turned on at the same time. In this case, a sensing operation through the sensing line VREF and a data output operation for outputting the data signal are separated (or distinguished) from each other in a time division manner of the data driver.

Besides, a digital data signal, an analog data signal, a gamma signal, or the like may be compensated according to the sensing result. The compensation circuit for generating a compensation signal (or a compensation voltage) based on the sensing result may be implemented inside the data driver, inside the timing controller, or inside a separate circuit.

As described above, FIG. 3 illustrates, for example, the sub-pixel having a 3T(Transistor)1C(Capacitor) structure including the switching transistor SW, the driving transistor DR, the capacitor Cst, the organic light emitting diode OLED, and the sensing transistor ST. However, when the compensation circuit CC is added to the sub-pixel, the sub-pixel may have various structures, such as 3T2C, 4T2C, 5TIC, and 6T2C.

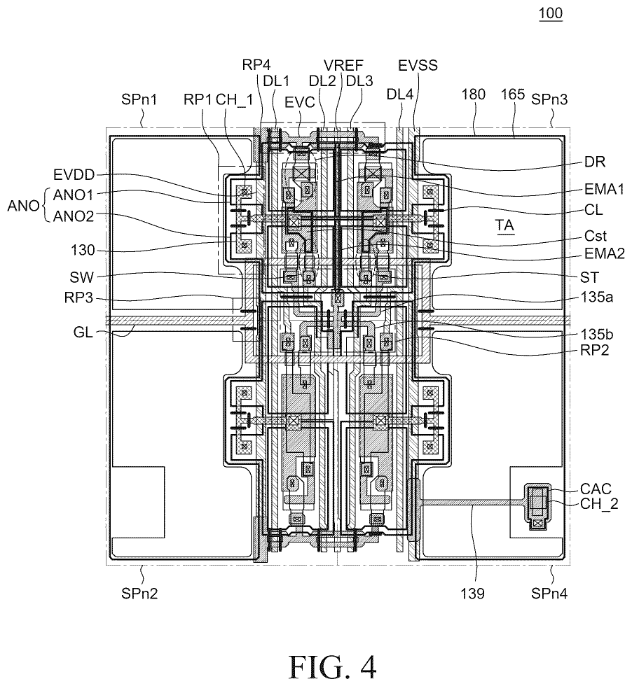

FIG. 4 is a plan view of a transparent display device according to a first embodiment of the present disclosure.

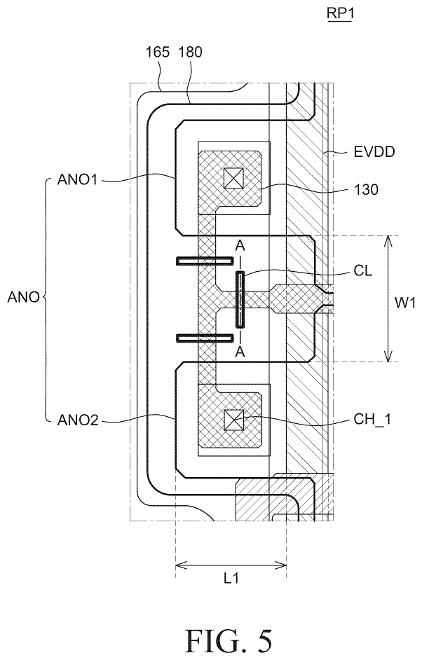

FIG. 5 is an enlarged view of a first repair part of FIG. 4 according to the first embodiment of the present disclosure.

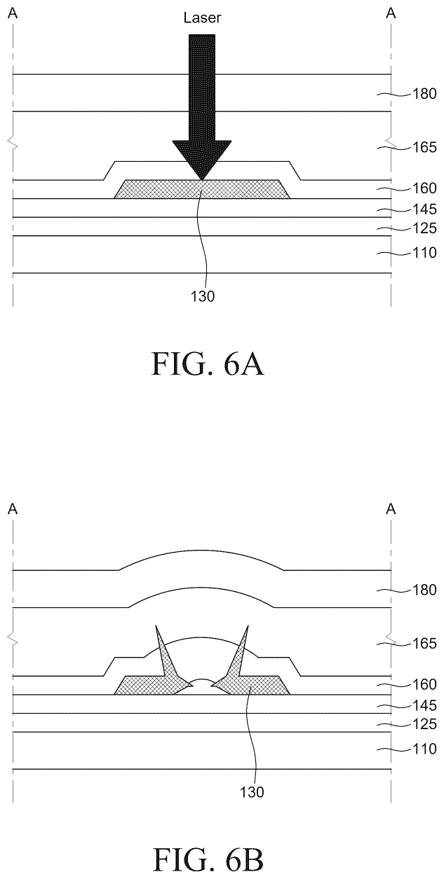

FIG. 6A and FIG. 6B are cross-sectional views taken along a line A-A of FIG. 5 according to the first embodiment of the present disclosure.

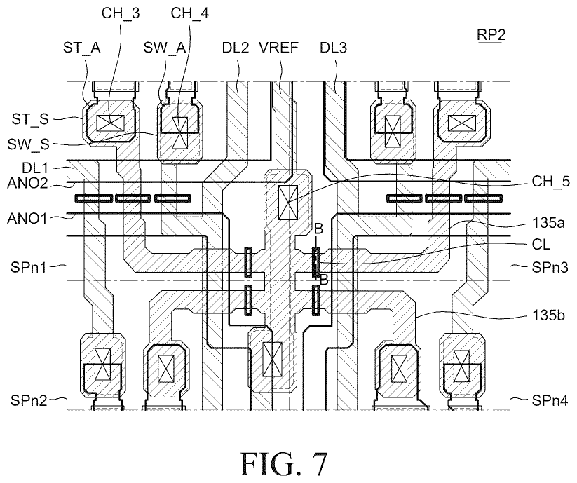

FIG. 7 is an enlarged view of a second repair part of FIG. 4 according to the first embodiment of the present disclosure.

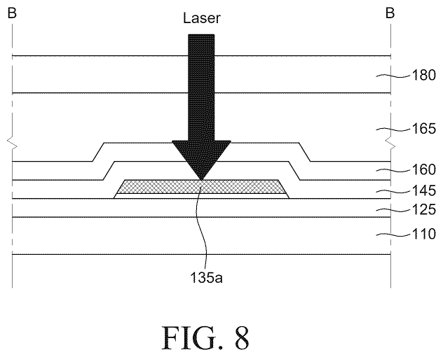

FIG. 8 is a cross-sectional view taken along a line B-B of FIG. 7 according to the first embodiment of the present disclosure.

FIG. 6A illustrates an example of a laser repair process of a first repair part RP1, and FIG. 6B is a cross-sectional view of the first repair part RP1 after the laser repair process.

Referring to FIG. 4, for example, a gate line GL may intersect first to fourth data lines DL1 to DL4 to define first to fourth sub-pixels SPn1 to SPn4 in a transparent display device 100 according to the first embodiment of the present disclosure.

Each of the first to fourth sub-pixels SPn1 to SPn4 may include two emission areas EMA1 and EMA2, i.e., a first emission area EMA1 and a second emission area EMA2, and one transmission area TA.

For example, the first to fourth sub-pixels SPn1 to SPn4 connected to the first to fourth data lines DL1 to DL4, respectively, may be commonly connected to the sensing line VREF. The sensing line VREF may be connected to the first sub-pixel SPn1 and the third sub-pixel SPn3 through a first sensing connection line 135a. Also, the sensing line VREF may be connected to the second sub-pixel SPn2 and the fourth sub-pixel SPn4 through a second sensing connection line 135b.

Herein, the first sensing connection line 135a and the second sensing connection line 135b may be connected to each other, but the present disclosure is not limited thereto. Also, the first sensing connection line 135a and the second sensing connection line 135b may be disposed on a gate wiring layer. However, the present disclosure is not limited thereto. Herein, the gate wiring layer may be the same layer as a layer on which the gate line GL is disposed.

Further, the power line EVDD may be disposed on one side of the first sub-pixel SPn1 and the second sub-pixel SPn2. For example, the first to fourth sub-pixels SPn1 to SPn4 may be connected to the power line EVDD through a power connection line EVC. Furthermore, the cathode power line EVSS may be disposed on one side of the third and fourth sub-pixels SPn3 and SPn4 and connected to the second electrode (not shown), which is a cathode.

In each of the first to fourth sub-pixels SPn1 to SPn4, a first anode ANO1 is disposed in the first emission area EMA1, and a second anode ANO2 is disposed in the second emission area EMA2 to constitute a first electrode ANO of the organic light emitting diode OLED. For example, the first anode ANO1 and the second anode ANO2 are connected to each other to constitute the first electrode ANO in each of the first to fourth sub-pixels SPn1 to SPn4.

The driving transistor DR, the capacitor Cst, the sensing transistor ST, and the switching transistor SW may be disposed in each of the first to fourth sub-pixels SPn1 to SPn4. The first emission area EMA1 may overlap the driving transistor DR, and the second emission area EMA2 may overlap the sensing transistor ST and the switching transistor SW.

The sensing line VREF may be connected to the sensing transistor ST of each of the first to fourth sub-pixels SPn1 to SPn4 through the first and second sensing connection lines 135a and 135b. The power line EVDD may be connected to the driving transistor DR of each of the first to fourth sub-pixels SPn1 to SPn4 through the power connection line EVC.

The gate line GL may be connected to each of the sensing and switching transistors ST and SW of the first to fourth sub-pixels SPn1 to SPn4.

Meanwhile, as described above, the cathode power line EVSS may be disposed to apply a low-potential voltage to the second electrode.

Herein, the cathode power line EVSS may be electrically connected to a cathode connection line 139 through a contact hole. The cathode connection line 139 may extend to the transmission area TA. The cathode connection line 139 may be disposed on the gate wiring layer.

For example, the cathode connection line 139 extending to the transmission area TA may be electrically connected to a cathode contact part CAC through the contact hole.

Also, for example, the cathode contact part CAC may be electrically connected to the second electrode through a cathode contact hole CH_2. The cathode contact part CAC may be disposed on a source/drain wiring layer. The cathode contact part CAC serves to lower a resistance by applying a low-potential voltage to the second electrode. Herein, the cathode contact hole CH_2 may be referred to as a second contact hole.

The first electrode ANO may include the first anode ANO1 and the second anode ANO2. The first anode ANO1 and the second anode ANO2 may be connected to each other through an anode connection line 130. The anode connection line 130 may extend from the source electrode or drain electrode of the driving transistor DR, and may be branched in the transmission area TA toward the first anode ANO1 and the second anode ANO2. For example, each of the first anode ANO1 and the second anode ANO2 may be electrically connected to an anode connection electrode AP through an anode contact hole CH_1.

The first repair part RP1 may be disposed in an area where the first anode ANO1 and the second anode ANO2 of the first electrode ANO are connected to each other.

When one of the emission areas EMA1 and EMA2 malfunctions due to foreign matter, which may be generated during the process, the first repair part RP1 may repair the sub-pixels SPn1 to SPn4 by disconnecting CL from the first anode ANO1 of the first emission area EMA1 or the second anode ANO2 of the second emission area EMA2 to repair the sub-pixels SPn1 to SPn4. In this case, the other one of the emission areas EMA1 and EMA2 which has not been short-circuited may operate normally.

Also, a second repair part RP2 may be disposed in an area where the first sensing connection line 135a and the second sensing connection line 135b connected to the sensing line VREF are branched to the first to fourth sub-pixels SPn1 to SPn4. When one of the emission areas EMA1 and EMA2 of the sub-pixels SPn1 to SPn4 malfunctions due to a short circuit of the first sensing connection line 135a or the second sensing connection line 135b, which may occur during the process, the second repair part RP2 may repair the sub-pixels SPn1 to SPn4 by disconnecting CL the first sensing connection line 135a or the second sensing connection line 135b. The second repair part RP2 may be disposed in an area where the sensing line VREF is connected to the first sensing connection line 135a and the second sensing connection line 135b, and the first to fourth sub-pixels SPn1 to SPn4 are adjacent to each other.

Further, a third repair part RP3 may be disposed in each of an area where the gate line GL is branched to the first and second sub-pixels SPn1 and SPn2 and an area where the gate line GL is branched to the third and fourth sub-pixels SPn3 and SPn4. When one of the emission areas EMA1 and EMA2 of the sub-pixels SPn1 to SPn4 malfunctions due to a short circuit of the branched gate line GL, which may occur during the process, the third repair part RP3 may repair the first to fourth sub-pixels SPn1 to SPn4 by disconnecting CL a part of the branched gate line GL. The third repair part RP3 may be disposed in an area where the gate line GL is branched to the first and second sub-pixels SPn1 and SPn2 or to the third and fourth sub-pixels SPn3 and SPn4, and the first and second sub-pixels SPn1 and SPn2 or the third and fourth sub-pixels SPn3 and SPn4 are adjacent to each other.

Furthermore, a fourth repair part RP4 may be disposed at upper ends of the first and third sub-pixels SPn1 and SPn3 or lower ends of the second and fourth sub-pixels SPn2 and SPn4 where the power connection line EVC is connected to the power line EVDD. When one of the emission areas EMA1 and EMA2 of the first to fourth sub-pixels SPn1 to SPn4 malfunctions due to a short circuit of the power connection line EVC, which may occur during the process, the fourth repair part RP4 may repair the first to fourth sub-pixels SPn1 to SPn4 by disconnecting CL from the power connection line EVC.

As described above, the first electrode ANO may be branched to the first anode ANO1 of the first emission area EMA1 and the second anode ANO2 of the second emission area EMA2 to provide the first repair part RP1. Details of the first repair part RP1 will be described below.

Rereferring to FIG. 4 through FIG. 6A and FIG. 6B, a light shielding layer may be disposed on a substrate 110.

The light shielding layer may serve to block the introduction of external light and suppress the generation of a light current in a thin film transistor.

The data lines DL1 to DL4, the power line EVDD, the sensing line VREF, and the cathode power line EVSS may be disposed on the same layer as the light shielding layer.

A buffer layer 125 may be disposed on the substrate 110 on which the light shielding layer, the data lines DL1 to DL4, the power line EVDD, the sensing line VREF, and the cathode power line EVSS are disposed. The buffer layer 125 serves to protect thin film transistors formed in the subsequent process from impurities, such as alkali ions, discharged from the light shielding layer.

For example, the buffer layer 125 may be made of silicon oxide (SiOx), silicon nitride (SiNx), or a multi-layer thereof.

A semiconductor layer of the driving transistor DR may be disposed on the buffer layer 125, and a lower capacitor electrode may be disposed to be spaced apart from the semiconductor layer.

Semiconductor layers of the sensing transistor ST and the switching transistor SW, respectively, may be disposed on the same layer as the semiconductor layer of the driving transistor DR. However, the present disclosure is not limited thereto.

The semiconductor layer and the lower capacitor electrode may be made of a silicon semiconductor or an oxide semiconductor. Also, the silicon semiconductor may include amorphous silicon or polycrystalline silicon.

Also, the semiconductor layer may include a drain region and a source region containing p-type or n-type impurities, and a channel region between the drain region and the source region. The lower capacitor electrode may also be doped with impurities to become conductive. However, the present disclosure is not limited thereto.

A gate insulating film may be disposed on the semiconductor layer and the lower capacitor electrode. For example, the gate insulating film may be made of silicon oxide (SiOx), silicon nitride (SiNx), or a multi-layer thereof.

The gate electrode of the driving transistor DR may be disposed on the gate insulating film in a predetermined region of the semiconductor layer, i.e., at a position corresponding to a channel when impurities are injected.

The gate electrodes of the sensing transistor ST and the switching transistor SW, and the gate line GL may be disposed on the same layer as the gate electrode of the driving transistor DR. Also, the source electrode and the drain electrode of the driving transistor DR may be disposed on the same layer as the gate electrode of the driving transistor DR. Further, the source electrodes and the drain electrodes of the sensing transistor ST and the switching transistor SW, respectively, may be disposed on the same layer as the gate electrode of the driving transistor DR. However, the present disclosure is not limited thereto.

The gate electrode, the gate line, the source electrode, and the drain electrode may be made of one or more materials selected from the group consisting of molybdenum (Mo), aluminum (Al), chromium (Cr), gold (Au), titanium (Ti), nickel (Ni), neodymium (Nd), and copper (Cu), or an alloy thereof. For example, the gate electrode, the gate line, the source electrode, and the drain electrode may be configured by a multi-layer made of materials selected from the group consisting of molybdenum (Mo), aluminum (Al), chromium (Cr), gold (Au), titanium (Ti), nickel (Ni), neodymium (Nd), and copper (Cu), or an alloy thereof. For example, the gate electrode, the gate line, the source electrode, and the drain electrode may be configured by a double layer of molybdenum/aluminum—neodymium or molybdenum/aluminum.

Herein, the driving transistor DR may be composed of the semiconductor layer, the gate electrode, the source electrode, and the drain electrode. Further, the lower capacitor electrode and the drain electrode, which serves as an upper capacitor electrode, may constitute the capacitor Cst.

An interlayer insulating film 145 may be disposed on the substrate 110 including the driving transistor DR and the capacitor Cst.

For example, the interlayer insulating film 145 may be made of silicon oxide (SiOx), silicon nitride (SiNx), or a multi-layer thereof.

The anode connection line 130 may be disposed on the interlayer insulating film 145.

For example, the anode connection line 130 may be configured by a single layer or a multi-layer.

For example, the anode connection line 130 may be connected to the source electrode or the drain electrode of the driving transistor DR. Also, the anode connection line 130 may extend to the first repair part RP1 and may be branched in the first repair part RP1 toward the first anode ANO1 and the second anode ANO2.

A passivation film 160 may be disposed on the substrate 110 including the anode connection line 130. The passivation film 160 is an insulating film serving to protect the underlying components, and may be made of silicon oxide (SiOx), silicon nitride (SiNx), or a multi-layer thereof.

An overcoating layer 165 may be disposed on the passivation film 160.

The overcoating layer 165 may be a planarization film for reducing a step difference on the underlying structure, and may be made of an organic material, such as polyimide, benzocyclobutene series resin, acrylate, etc.

For example, the overcoating layer 165 may be formed through a spin on glass (SOG) method for coating the organic material in a liquid state and then curing the organic material.

An organic light emitting diode may be disposed on the overcoating layer 165.

More specifically, the first electrode ANO may be disposed on the overcoating layer 165. The first electrode ANO serves as a pixel electrode and may be connected to the source electrode or the drain electrode of the driving transistor DR through the anode connection line 130 connected to the first electrode ANO.

The first electrode ANO may include the first anode ANO1 and the second anode ANO2. The first anode ANO1 and the second anode ANO2 may be connected to each other through the anode connection line 130. Each of the first anode ANO1 and the second anode ANO2 may be electrically connected to the anode connection line 130 through, for example, the anode contact hole CH_1.

The first electrode ANO may be made of a transparent conductive material, such as indium tin oxide (ITO), indium zinc oxide (IZO), or zinc oxide (ZnO). For example, the transparent display device 100 according to the present disclosure has a top emission structure, and the first electrode ANO may be configured by a reflective electrode. Therefore, the first electrode ANO may further include a reflective layer. For example, the reflective layer may be made of aluminum (Al), copper (Cu), silver (Ag), nickel (Ni), or an alloy thereof. Preferably, the reflective layer may be made of an Ag/Pd/Cu (APC) alloy.

Further, a bank layer 180 defining the first to fourth sub-pixels SPn1 to SPn4 may be disposed on the substrate 110 including the first electrode ANO.

For example, the bank layer 180 may be made of an organic material, such as polyimide, benzocyclobutene series resin, acrylate, etc.

An emission layer in contact with the first electrode ANO may be disposed on the entire surface of the substrate 110. The emission layer is a layer in which electrons and holes are recombined to emit light. A hole injection layer or a hole transport layer may be provided between the emission layer and the first electrode ANO. An electron transport layer or an electron injection layer may be provided on the emission layer.

The second electrode may be disposed on the emission layer. The second electrode is a cathode, and may be located on the entire surface of a display part. Also, the second electrode may be made of magnesium (Mg), calcium (Ca), aluminum (Al), silver (Ag), or an alloy thereof, each having a low work function. The second electrode may be a transmissive electrode and may be thin enough to transmit light. Further, for example, the second electrode may be a transmissive electrode and may be made of a transparent conductive material, such as indium tin oxide (ITO), indium zinc oxide (IZO), or zinc oxide (ZnO).

As described above, in the first embodiment of the present disclosure, the source electrode or the drain electrode of the driving transistor DR may be connected to the first anode ANO1 and the second anode ANO2 through the anode connection line 130. For example, the anode connection line 130 may be connected to the drain electrode through a via hole formed in the passivation film 160 and the overcoating layer 165. As such, the anode connection line 130 connected to the source electrode or the drain electrode of the driving transistor DR may extend to the first repair part RP1. As shown in FIG. 4 and FIG. 5, the anode connection line 130 may be branched in the first repair part RP1 toward the first anode ANO1 and the second anode ANO2. Herein, when one of the emission areas EMA1 and EMA2 malfunctions due to foreign matter, which may be generated during the process, the first repair part RP1 may short-circuit (CL) the first anode ANO1 or the second anode ANO2 to repair the first emission area EMA1 or the second emission area EMA2.

For example, in the first embodiment of the present disclosure, a portion of the anode connection line 130 may be short-circuited (CL) by irradiating a laser from above the first to fourth sub-pixels SPn1 to SPn4. Herein, the short circuit (CL) refers to a physical short circuit of the anode connection line 130 by irradiating the anode connection line 130 with a laser and bursting the anode connection line 130. Referring to FIG. 6B, it can be seen that a central portion of the anode connection line 130 is burst up and disconnected after laser irradiation. As a result, it can be seen that the passivation film 160, the overcoating layer 165, and the bank layer 180 on the anode connection line 130 protrude upwards.

For example, a laser having a wavelength of 532 nm or 1064 nm may be used. However, the present disclosure is not limited thereto.

For example, if the first emission area EMA1 of the first sub-pixel SPn1 is darkened, a portion of the anode connection line 130 branched toward the first anode ANO1 may be short-circuited (CL). Also, if the second emission area EMA2 of the first sub-pixel SPn1 is darkened, a portion of the anode connection line 130 branched toward the second anode ANO2 may be short-circuited (CL). Further, for example, if both the first emission area EMA1 and the second emission area EMA2 of the first sub-pixel SPn1 are darkened, a portion of the anode connection line 130 before being branched toward the first anode ANO1 and the second anode ANO2 may be short-circuited (CL).

As described above, in the first embodiment of the present disclosure, the first repair part RP1 is provided. Thus, when some emission areas EMA1 and EMA2 of some of the first to fourth sub-pixels SPn1 to SPn4 malfunction, only the malfunctioning emission areas EMA1 and EMA2 can be darkened.

However, in the first embodiment of the present disclosure, the first anode ANO1 and the second anode ANO2 of a metal layer cannot be disposed on the anode connection line 130 to be repaired by irradiating a laser from above the first to fourth sub-pixels SPn1 to SPn4. Therefore, a loss of the transmission area TA may occur in proportion to a width W1 of the space where the first anode ANO1 and the second anode ANO2 cannot be disposed.

Also, the first repair part RP1 is spaced apart from the power line EVDD by a predetermined distance. Thus, a loss of the transmission area TA may occur in proportion to the distance L1.

As described above, in the first embodiment of the present disclosure, the second repair part RP2 may be provided to repair the first to fourth sub-pixels SPn1 to SPn4 which malfunction due to a short circuit of the first sensing connection line 135a or the second sensing connection line 135b.

Referring to FIG. 4, FIG. 7, and FIG. 8, the light shielding layer may be disposed on the substrate 110.

The data lines DL1 to DL4, the power line EVDD, the sensing line VREF, and the cathode power line EVSS may be disposed on the same layer as the light shielding layer.

The buffer layer 125 may be disposed on the substrate 110 on which the light shielding layer, the data lines DL1 to DL4, the power line EVDD, the sensing line VREF, and the cathode power line EVSS are disposed.

The semiconductor layer of the driving transistor DR may be disposed on the buffer layer 125, and the lower capacitor electrode may be disposed to be spaced apart from the semiconductor layer.

Semiconductor layers ST_A and SW_A of the sensing transistor ST and the switching transistor SW, respectively, may be disposed on the same layer as the semiconductor layer of the driving transistor DR. However, the present disclosure is not limited thereto.

The gate insulating film may be disposed on the semiconductor layer and the lower capacitor electrode.

The gate electrode of the driving transistor DR may be disposed on the gate insulating film in a predetermined region of the semiconductor layer, i.e., at a position corresponding to a channel when impurities are injected.

The gate electrodes of the sensing transistor ST and the switching transistor SW, and the gate line GL may be disposed on the same layer as the gate electrode of the driving transistor DR. Also, the source electrode and the drain electrode of the driving transistor DR may be disposed on the same layer as the gate electrode of the driving transistor DR. Further, source electrodes ST_S and SW_S and the drain electrodes of the sensing transistor ST and the switching transistor SW, respectively, may be disposed on the same layer as the gate electrode of the driving transistor DR. However, the present disclosure is not limited thereto. Furthermore, the first sensing connection line 135a and the second sensing connection line 135b may be disposed on the same layer as the gate electrode of the driving transistor DR.

For example, the source electrode ST_S of the sensing transistor ST may be electrically connected to the semiconductor layer ST_A of the sensing transistor ST through a source contact hole CH_3. Also, the source electrode SW_S of the switching transistor SW may be electrically connected to the semiconductor layer SW_A of the switching transistor SW through a source contact hole CH_4. Further, the source electrode SW_S of the switching transistor SW of the first sub-pixel SPn1 may be electrically connected to the second data line DL2 through the source contact hole CH_4. Furthermore, the source electrode SW_S of the switching transistor SW of the third sub-pixel SPn3 may be electrically connected to the third data line DL3 through the source contact hole CH_4. For example, the source electrode SW_S of the switching transistor SW of the second sub-pixel SPn2 may be electrically connected to the first data line DL1 through the source contact hole CH_4. Also, the source electrode SW_S of the switching transistor SW of the fourth sub-pixel SPn4 may be electrically connected to the fourth data line DL4 through the source contact hole CH_4. The source contact hole CH_3 of the sensing transistor ST may be referred to as a third contact hole, and the source contact hole CH_4 of the switching transistor SW may be referred to as a fourth contact hole.

For example, the first sensing connection line 135a and the second sensing connection line 135b may be electrically connected to the sensing line VREF through a sensing line contact hole CH_5. Also, the first sensing connection line 135a and the second sensing connection line 135b may be connected to each other. However, the present disclosure is not limited thereto. The sensing line contact hole CH_5 may be referred to as a fifth contact hole.

For example, the sensing line VREF may be connected to the first sub-pixel SPn1 and the third sub-pixel SPn3 through the first sensing connection line 135a. Also, the sensing line VREF may be connected to the second sub-pixel SPn2 and the fourth sub-pixel SPn4 through the second sensing connection line 135b.

Further, for example, the source electrodes ST_S of the sensing transistors ST of the first sub-pixel SPn1 and the third sub-pixel SPn3 may extend and constitute the first sensing connection line 135a. Furthermore, the source electrodes ST_S of the sensing transistors ST of the second sub-pixel SPn2 and the fourth sub-pixel SPn4 may extend and constitute the second sensing connection line 135b.

Also, the interlayer insulating film 145 may be disposed on the substrate 110 including the driving transistor DR, the capacitor Cst, the switching transistor SW, the first sensing connection line 135a, and the second sensing connection line 135b.

The passivation film 160 may be disposed on the interlayer insulating film 145.

The overcoating layer 165 may be disposed on the passivation film 160.

The organic light emitting diode may be disposed on the overcoating layer 165.

The bank layer 180 defining the first to fourth sub-pixels SPn1 to SPn4 may be disposed on the substrate 110 including the first electrode ANO of the organic light emitting diode.

As described above, in the first embodiment of the present disclosure, the second repair part RP2 may be disposed in an area where each of the first sensing connection line 135a and the second sensing connection line 135b connected to the sensing line VREF is branched to the first to fourth sub-pixels SPn1 to SPn4.

When one of the emission areas EMA1 and EMA2 of the sub-pixels SPn1 to SPn4 malfunctions due to a short circuit of the first sensing connection line 135a or the second sensing connection line 135b, which may occur during the process, the second repair part RP2 may short-circuit (CL) the first sensing connection line 135a or the second sensing connection line 135b to short-circuit the first to fourth sub-pixels SPn1 to SPn4.

For example, in the first embodiment of the present disclosure, a portion of the first sensing connection line 135a or a portion the second sensing connection line 135b may be short-circuited (CL) by irradiating a laser from above the first to fourth sub-pixels SPn1 to SPn4.

For example, a laser having a wavelength of 532 nm or 1064 nm may be used. However, the present disclosure is not limited thereto.

Herein, for example, if the second emission area EMA2 of the first sub-pixel SPn1 or the second emission area EMA2 of the third sub-pixel SPn3 is darkened, a portion of the first sensing connection line 135a may be short-circuited (CL). Also, if the first emission area EMA1 of the second sub-pixel SPn2 or the first emission area EMA1 of the fourth sub-pixel SPn4 is darkened, a portion of the second sensing connection line 135b may be short-circuited (CL).

As described above, in the first embodiment of the present disclosure, the second repair part RP2 is provided. Thus, when some emission areas EMA1 and EMA2 of some of the first to fourth sub-pixels SPn1 to SPn4 malfunction, only the malfunctioning emission areas EMA1 and EMA2 can be darkened.

However, in the first embodiment of the present disclosure, the first anode ANO1 and the second anode ANO2 of the metal layer cannot be disposed on the first sensing connection line 135a and the second sensing connection line 135b to be repaired by irradiating a laser from above the first to fourth sub-pixels SPn1 to SPn4. Therefore, a loss of an aperture ratio may occur in proportion to the corresponding area.

Accordingly, in a second embodiment of the present disclosure, instead of a metal line, an oxide semiconductor layer is used as a line for repair. Thus, a repair is performed by irradiating a laser from below a sub-pixel. Thus, it is possible to improve an aperture ratio and transparency. Details thereof will be described below with reference to the accompanying drawings.

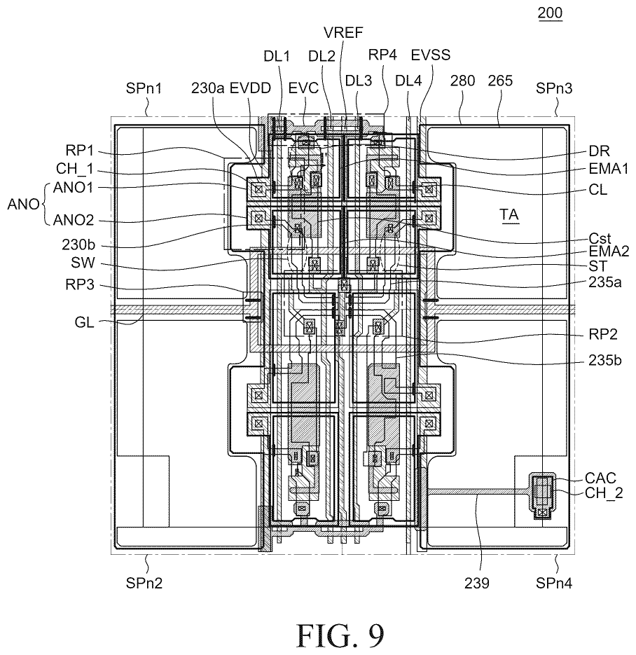

FIG. 9 is a plan view of a transparent display device according to the second embodiment of the present disclosure.

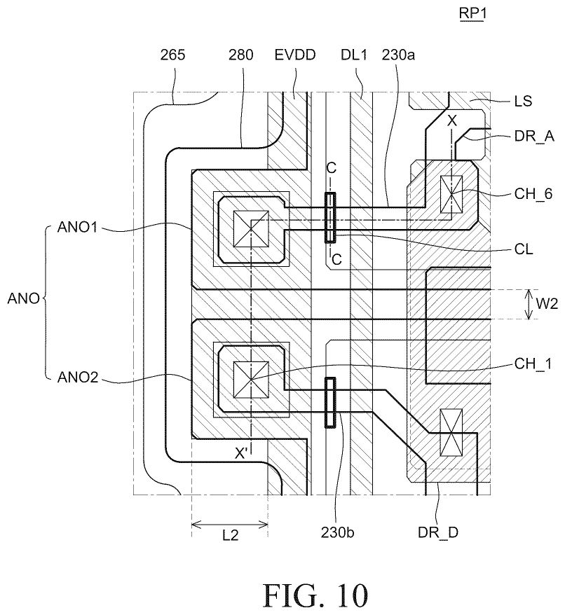

FIG. 10 is an enlarged view of a first repair part of FIG. 9 according to the second embodiment of the present disclosure.

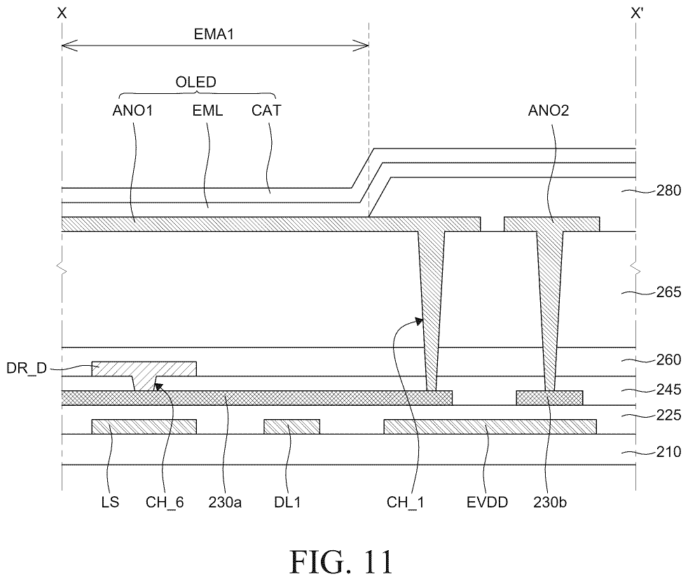

FIG. 11 is a cross-sectional view taken along a line X-X′ of FIG. 10 according to the second embodiment of the present disclosure.

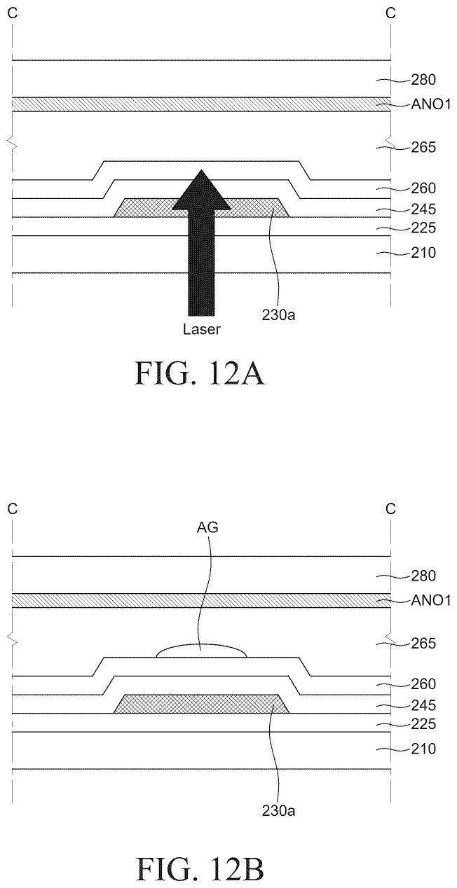

FIG. 12A and FIG. 12B are cross-sectional views taken along a line C-C of FIG. 10 according to the second embodiment of the present disclosure.

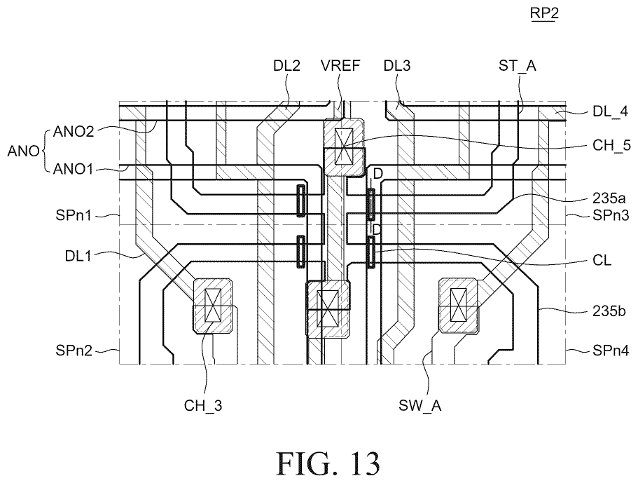

FIG. 13 is an enlarged view of a second repair part of FIG. 9 according to the second embodiment of the present disclosure.

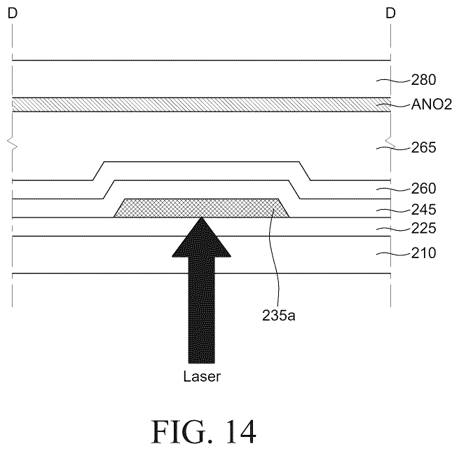

FIG. 14 is a cross-sectional view taken along a line D-D of FIG. 13 according to the second embodiment of the present disclosure.

Herein, FIG. 12A illustrates an example of a laser repair process of the first repair part RP1, and FIG. 12B is a cross-sectional view of the first repair part RP1 after the laser repair process.

A transparent display device 200 according to the second embodiment of the present disclosure of FIG. 9 through FIG. 14 is substantially the same as the first embodiment of the present disclosure of FIG. 4 through FIG. 8 except the first repair part RP1 and the second repair part RP2.

Referring to FIG. 9, for example, the gate line GL may intersect the first to fourth data lines DL1 to DL4 to define the first to fourth sub-pixels SPn1 to SPn4 in the transparent display device 200 according to the second embodiment of the present disclosure.

Each of the first to fourth sub-pixels SPn1 to SPn4 may include two emission areas EMA1 and EMA2, i.e., the first emission area EMA1 and the second emission area EMA2, and one transmission area TA.

For example, the first to fourth sub-pixels SPn1 to SPn4 connected to the first to fourth data lines DL1 to DL4, respectively, may be commonly connected to the sensing line VREF. The sensing line VREF may be connected to the first sub-pixel SPn1 and the third sub-pixel SPn3 through a first sensing connection line 235a. Also, the sensing line VREF may be connected to the second sub-pixel SPn2 and the fourth sub-pixel SPn4 through a second sensing connection line 235b.

Also, the first sensing connection line 235a and the second sensing connection line 235b may be connected to each other, but the present disclosure is not limited thereto. Also, the first sensing connection line 235a and the second sensing connection line 235b may be disposed on a semiconductor layer. However, the present disclosure is not limited thereto. Herein, the semiconductor layer may be the same layer as a layer on which the semiconductor layers of the transistors DR, ST and SW are disposed.

Further, the power line EVDD may be disposed on one side of the first sub-pixel SPn1 and the second sub-pixel SPn2, specifically, on one side of the emission areas EMA1 and EMA2 of the first sub-pixel SPn1 and the second sub-pixel SPn2. For example, the first to fourth sub-pixels SPn1 to SPn4 may be connected to the power line EVDD through the power connection line EVC. Furthermore, the cathode power line EVSS may be disposed on one side of the third and fourth sub-pixels SPn3 and SPn4, specifically, on one side of the emission areas EMA1 and EMA2 of the third and fourth sub-pixels SPn3 and SPn4. Also, the cathode power line EVSS may be connected to the second electrode (not shown), which is a cathode.

In each of the first to fourth sub-pixels SPn1 to SPn4, the first anode ANO1 is disposed in the first emission area EMA1, and the second anode ANO2 is disposed in the second emission area EMA2 to constitute the first electrode ANO of the organic light emitting diode. For example, the first anode ANO1 and the second anode ANO2 are connected to each other to constitute the first electrode ANO in each of the first to fourth sub-pixels SPn1 to SPn4.

The driving transistor DR, the capacitor Cst, the sensing transistor ST, and the switching transistor SW may be disposed in each of the first to fourth sub-pixels SPn1 to SPn4. The first emission area EMA1 may overlap the driving transistor DR, and the second emission area EMA2 may overlap the sensing transistor ST and the switching transistor SW. however, the present disclosure is not limited thereto.

The sensing line VREF may be connected to the sensing transistor ST of each of the first to fourth sub-pixels SPn1 to SPn4 through the first and second sensing connection lines 235a and 235b.

Also, the power line EVDD may be connected to the driving transistor DR of each of the first to fourth sub-pixels SPn1 to SPn4 through the power connection line EVC.

The gate line GL may be connected to each of the sensing and switching transistors ST and SW of the first to fourth sub-pixels SPn1 to SPn4.

Meanwhile, as described above, the cathode power line EVSS may be disposed to apply a low-potential voltage to the second electrode.

Herein, the cathode power line EVSS may be electrically connected to a cathode connection line 239 through a contact hole. The cathode connection line 239 may extend to the transmission area TA. The cathode connection line 239 may be disposed on the gate wiring layer. However, the present disclosure is not limited thereto.

For example, the cathode connection line 239 extending to the transmission area TA may be electrically connected to the cathode contact part CAC through the contact hole.

Also, for example, the cathode contact part CAC may be electrically connected to the second electrode through the cathode contact hole CH_2. The cathode contact part CAC may be disposed on the source/drain wiring layer. The cathode contact part CAC serves to lower a resistance by applying a low-potential voltage to the second electrode. Herein, the cathode contact hole CH_2 may be referred to as a second contact hole.

The first electrode ANO may include the first anode ANO1 and the second anode ANO2. Each of the first anode ANO1 and the second anode ANO2 may be connected to a first anode connection line 230a and a second anode connection line 230b. Further, for example, the first anode ANO1 and the second anode ANO2 may be connected to each other through the first anode connection line 230a and the second anode connection line 230b connected to the source electrode or a drain electrode DR_D of the driving transistor DR.

The first anode connection line 230a and the second anode connection line 230b may be disposed on a semiconductor layer. However, the present disclosure is not limited thereto. Further, the first anode connection line 230a and the second anode connection line 230b may extend from a semiconductor layer DR_A of the driving transistor DR to the transmission area TA. Furthermore, the first anode connection line 230a and the second anode connection line 230b may be electrically connected to the first anode ANO1 and the second anode ANO2, respectively, through the anode contact hole CH_1. Herein, the anode contact hole CH_1 may be referred to as a first contact hole. Also, the first anode connection line 230a and the second anode connection line 230b disposed on the semiconductor layer may be made of a transparent material.

The first repair part RP1 may be disposed in an area where the first anode ANO1 and the second anode ANO2 of the first electrode ANO are connected to the first anode connection line 230a and the second anode connection line 230b.

When one of the emission areas EMA1 and EMA2 malfunctions due to foreign matter, which may be generated during the process, the first repair part RP1 may short-circuit the first anode ANO1 of the first emission area EMA1 or the second anode ANO2 of the second emission area EMA2 to repair the sub-pixels SPn1 to SPn4. In this case, the other one of the emission areas EMA1 and EMA2 which has not been short-circuited may operate normally.

Also, the second repair part RP2 may be disposed in an area where the first sensing connection line 235a and the second sensing connection line 235b connected to the sensing line VREF are branched to the first to fourth sub-pixels SPn1 to SPn4. When one of the emission areas EMA1 and EMA2 of the sub-pixels SPn1 to SPn4 malfunctions due to a short circuit of the first sensing connection line 235a or the second sensing connection line 235b, which may occur during the process, the second repair part RP2 may short-circuit (CL) the first sensing connection line 235a or the second sensing connection line 235b to short-circuit the first to fourth sub-pixels SPn1 to SPn4. Therefore, the second repair part RP2 may be disposed in an area where the sensing line VREF is connected to the first sensing connection line 235a and the second sensing connection line 235b, and the first to fourth sub-pixels SPn1 to SPn4 are adjacent to each other.

Further, the third repair part RP3 may be disposed in each of an area where the gate line GL is branched to the first and second sub-pixels SPn1 and SPn2 and an area where the gate line GL is branched to the third and fourth sub-pixels SPn3 and SPn4. When one of the emission areas EMA1 and EMA2 of the sub-pixels SPn1 to SPn4 malfunctions due to a short circuit of the branched gate line GL, which may occur during the process, the third repair part RP3 may short-circuit the first to fourth sub-pixels SPn1 to SPn4 by short-circuiting (CL) a part of the branched gate line GL. The third repair part RP3 may be disposed in an area where the gate line GL is branched to the first and second sub-pixels SPn1 and SPn2 or to the third and fourth sub-pixels SPn3 and SPn4, and the first and second sub-pixels SPn1 and SPn2 or the third and fourth sub-pixels SPn3 and SPn4 are adjacent to each other.

Furthermore, the fourth repair part RP4 may be disposed at upper ends of the first and third sub-pixels SPn1 and SPn3 or lower ends of the second and fourth sub-pixels SPn2 and SPn4 where the power connection line EVC is connected to the power line EVDD. When one of the emission areas EMA1 and EMA2 of the first to fourth sub-pixels SPn1 to SPn4 malfunctions due to a short circuit of the power connection line EVC, which may occur during the process, the fourth repair part RP4 may short-circuit the first to fourth sub-pixels SPn1 to SPn4 by short-circuiting (CL) the power connection line EVC.

As described above, the first repair part RP1 may be disposed in an area where the first anode ANO1 and the second anode ANO2 are connected to the first anode connection line 230a and the second anode connection line 230b. Details of the first repair part RP1 will be described below.

Rereferring to FIG. 9 through FIG. 12, a light shielding layer LS may be disposed on a substrate 210.

The light shielding layer LS may serve to block the introduction of external light and suppress the generation of a light current in a thin film transistor.

The data lines DL1 to DL4, the power line EVDD, the sensing line VREF, and the cathode power line EVSS may be disposed on the same layer as the light shielding layer LS.

A buffer layer 225 may be disposed on the substrate 210 on which the light shielding layer LS, the data lines DL1 to DL4, the power line EVDD, the sensing line VREF, and the cathode power line EVSS are disposed. The buffer layer 225 serves to protect thin film transistors formed in the subsequent process from impurities, such as alkali ions, discharged from the light shielding layer LS.

For example, the buffer layer 225 may be made of silicon oxide (SiOx), silicon nitride (SiNx), or a multi-layer thereof.

The semiconductor layer DR_A of the driving transistor DR may be disposed on the buffer layer 225.

The semiconductor layers of the sensing transistor ST and the switching transistor SW, respectively, may be disposed on the same layer as the semiconductor layer DR_A of the driving transistor DR.

For example, the semiconductor layer DR_A of the driving transistor DR may extend toward the first repair part RP1 and constitute the first anode connection line 230a and the second anode connection line 230b. The first anode connection line 230a and the second anode connection line 230b may be electrically connected to the first anode ANO1 and the second anode ANO2, respectively. That is, for example, the first anode connection line 230a and the second anode connection line 230b may extend from the semiconductor layer DR_A of the driving transistor DR to the transmission area TA. Also, the first anode connection line 230a and the second anode connection line 230b may be electrically connected to the first anode ANO1 and the second anode ANO2, respectively, through the anode contact hole CH_1.

For example, the semiconductor layer DR_A, the first anode connection line 230a, and the second anode connection line 230b may be made of a silicon semiconductor or an oxide semiconductor. The silicon semiconductor may include amorphous silicon or polycrystalline silicon.

Also, the semiconductor layer DR_A may include a drain region and a source region containing p-type or n-type impurities, and a channel region between the drain region and the source region. The first anode connection line 230a and the second anode connection line 230b may be doped with impurities to become conductive. However, the present disclosure is not limited thereto.

A gate insulating film may be disposed on the semiconductor layer DR_A, the first anode connection line 230a, and the second anode connection line 230b.

For example, the gate insulating film may be made of silicon oxide (SiOx), silicon nitride (SiNx), or a multi-layer thereof.

For example, the gate electrode of the driving transistor DR may be disposed on the gate insulating film in a predetermined region of the semiconductor layer DR_A, i.e., at a position corresponding to a channel when impurities are injected.

The gate electrodes of the sensing transistor ST and the switching transistor SW, and the gate line GL may be disposed on the same layer as the gate electrode of the driving transistor DR. Also, the source electrode and the drain electrode DR_D of the driving transistor DR may be disposed on the same layer as the gate electrode of the driving transistor DR. Further, the source electrodes and the drain electrodes of the sensing transistor ST and the switching transistor SW, respectively, may be disposed on the same layer as the gate electrode of the driving transistor DR. However, the present disclosure is not limited thereto. Herein, for example, the drain electrode DR_D of the driving transistor DR may extend to overlap the light shielding layer LS and constitute the capacitor Cst together with the light shielding layer LS. However, the present disclosure is not limited thereto.

For example, the source electrode or the drain electrode DR_D of the driving transistor DR may be electrically connected to the first anode connection line 230a and the second anode connection line 230 through a sixth contact hole CH_6. Thus, the first anode ANO1 and the second anode ANO2 may be connected to each other through the source electrode or the drain electrode DR_D of the driving transistor DR connected to the first anode connection line 230a and the second anode connection line 230b.

For example, the gate electrode, the gate line GL, the source electrode, and the drain electrode DR_D may be made of one or more materials selected from the group consisting of molybdenum (Mo), aluminum (Al), chromium (Cr), gold (Au), titanium (Ti), nickel (Ni), neodymium (Nd), and copper (Cu), or an alloy thereof. Also, for example, the gate electrode, the gate line GL, the source electrode, and the drain electrode DR_D may be configured by a multi-layer made of materials selected from the group consisting of molybdenum (Mo), aluminum (Al), chromium (Cr), gold (Au), titanium (Ti), nickel (Ni), neodymium (Nd), and copper (Cu), or an alloy thereof. For example, the gate electrode, the gate line GL, the source electrode, and the drain electrode DR_D may be configured by a double layer of molybdenum/aluminum—neodymium or molybdenum/aluminum.

Herein, the driving transistor DR may be composed of the semiconductor layer DR_A, the gate electrode, the source electrode, and the drain electrode DR_D.

An interlayer insulating film 245 may be disposed on the substrate 210 including the driving transistor DR and the capacitor Cst.

For example, the interlayer insulating film 245 may be made of silicon oxide (SiOx), silicon nitride (SiNx), or a multi-layer thereof.

A passivation film 260 may be disposed on the interlayer insulating film 245. For example, the passivation film 260 is an insulating film serving to protect the underlying components, and may be made of silicon oxide (SiOx), silicon nitride (SiNx), or a multi-layer thereof.

An overcoating layer 265 may be disposed on the passivation film 260.

The overcoating layer 265 may be a planarization film for reducing a step difference on the underlying structure, and may be made of an organic material, such as polyimide, benzocyclobutene series resin, acrylate, etc.

For example, the overcoating layer 265 may be formed through a spin on glass (SOG) method for coating the organic material in a liquid state and then curing the organic material.

The organic light emitting diode OLED may be disposed on the overcoating layer 265.

More specifically, the first electrode ANO may be disposed on the overcoating layer 265. The first electrode ANO serves as a pixel electrode. The first electrode ANO may be connected to the source electrode or the drain electrode DR_D of the driving transistor DR through the first anode connection line 230a and the second anode connection line 230b connected to the first electrode ANO. For example, the second anode connection line 230b may be connected to the first sensing connection line 235a or the second sensing connection line 235b through the sensing transistor ST, but is not limited thereto.

The first electrode ANO may include the first anode ANO1 and the second anode ANO2. The first anode ANO1 and the second anode ANO2 may be connected to each other through the first anode ANO1 and the second anode ANO2 connected to the source electrode or the drain electrode DR_D of the driving transistor DR. Each of the first anode ANO1 and the second anode ANO2 may be electrically connected to the first anode connection line 230a and the second anode connection line 230b through, for example, the anode contact hole CH_1. Herein, the anode contact hole CH_1 may be referred to as a first contact hole.

The first electrode ANO may be made of a transparent conductive material, such as indium tin oxide (ITO), indium zinc oxide (IZO), or zinc oxide (ZnO). For example, the transparent display device 200 according to the present disclosure has a top emission structure, and the first electrode ANO may be configured by a reflective electrode. Therefore, the first electrode ANO may further include a reflective layer. For example, the reflective layer may be made of aluminum (Al), copper (Cu), silver (Ag), nickel (Ni), or an alloy thereof. Preferably, the reflective layer may be made of an Ag/Pd/Cu (APC) alloy.

Further, a bank layer 280 defining the first to fourth sub-pixels SPn1 to SPn4 may be disposed on the substrate 210 including the first electrode ANO.

For example, the bank layer 280 may be made of an organic material, such as polyimide, benzocyclobutene series resin, acrylate, etc.

An emission layer EML in contact with the first electrode ANO may be disposed on the entire surface of the substrate 110. The emission layer EML is a layer in which electrons and holes are recombined to emit light. A hole injection layer or a hole transport layer may be provided between the emission layer EML and the first electrode ANO. An electron transport layer or an electron injection layer may be provided on the emission layer EML.

A second electrode CAT may be disposed on the emission layer EML. The second electrode CAT is a cathode, and may be located on the entire surface of a display part. Also, the second electrode CAT may be made of magnesium (Mg), calcium (Ca), aluminum (Al), silver (Ag), or an alloy thereof, each having a low work function. The second electrode CAT may be a transmissive electrode and may be thin enough to transmit light.

As described above, in the second embodiment of the present disclosure, the source electrode or the drain electrode DR_D of the driving transistor DR may be connected to the first anode ANO1 and the second anode ANO2 through the first anode connection line 230a and the second anode connection line 230b, respectively. For example, the source electrode or the drain electrode DR_D of the driving transistor DR may be electrically connected to the first anode connection line 230a and the second anode connection line 230b through the sixth contact hole CH_6 formed in the interlayer insulating film 245. The first anode connection line 230a and the second anode connection line 230b connected to the source electrode or the drain electrode DR_D of the driving transistor DR may extend to the first repair part RP1 in the transmission area TA. As shown in FIG. 9 and FIG. 10, the first anode connection line 230a and the second anode connection line 230b may be electrically connected to the first anode ANO1 and the second anode ANO2, respectively, in the first repair part RP1. Herein, when one of the emission areas EMA1 and EMA2 malfunctions due to foreign matter, which may be generated during the process, the first repair part RP1 may short-circuit the first anode ANO1 or the second anode ANO2 to repair the first emission area EMA1 or the second emission area EMA2.

For example, in the second embodiment of the present disclosure, a portion of the first anode connection line 230a or a portion of the second anode connection line 230b may be electrically short-circuited (CL) by irradiating a laser from below the substrate 210. Herein, the electrical short circuit (CL) refers to making the first anode connection line 230a or the second anode connection line 230b non-conductive by irradiating the first anode connection line 230a or the second anode connection line 230b with a specific laser and increasing a resistance of the first anode connection line 230a or the second anode connection line 230b made of an oxide semiconductor. Referring to FIG. 12B, it can be seen that the first anode connection line 230a becomes non-conductive after laser irradiation, and an air gap is formed between the passivation film 260 and the overcoating layer 265. Also, it can be seen that the overcoating layer 265 and the bank layer 280 on a repair area have flat surfaces without any changes.

For example, a laser having a wavelength of 256 nm may be used. However, the present disclosure is not limited thereto.

For example, if the first emission area EMA1 of the first sub-pixel SPn1 is darkened, a portion of the first anode connection line 230 electrically connected to the first anode ANO1 may be short-circuited (CL). Also, if the second emission area EMA2 of the first sub-pixel SPn1 is darkened, a portion of the second anode connection line 230b connected to the second anode ANO2 may be short-circuited (CL). Further, for example, if both the first emission area EMA1 and the second emission area EMA2 of the first sub-pixel SPn1 are darkened, a portion of the first anode connection line 230a and a portion of the second anode connection line 230b may be short-circuited (CL).

As described above, in the second embodiment of the present disclosure, the first repair part RP1 is provided. Thus, when some emission areas EMA1 and EMA2 of some of the first to fourth sub-pixels SPn1 to SPn4 malfunction, only the malfunctioning emission areas EMA1 and EMA2 can be darkened.

Also, in the second embodiment of the present disclosure, a laser is irradiated from below the substrate 210. Thus, the first anode ANO1 and the second anode ANO2 of a metal layer can be disposed on the first anode connection line 230a and the second anode connection line 230b to be repaired. Therefore, a width W2 between the first anode ANO1 and the second anode ANO2 can be reduced.

Further, in the second embodiment of the present disclosure, the first repair part RP1 is provided to partially overlap the power line EVDD. Thus, a distance L2 can be reduced. Therefore, it can be seen that in the second embodiment of the present disclosure, the transmission area TA increases in proportion to a width difference (W1-W2) and a distance difference (L1-L2), which results in an increase in transparency by about 0.9%. Further, for example, the first repair part RP1 may partially overlap the bank layer 280. Furthermore, for example, the first repair part RP1 may partially overlap a black matrix.

As described above, in the second embodiment of the present disclosure, the second repair part RP2 may be provided to repair the first to fourth sub-pixels SPn1 to SPn4 which malfunction due to a short circuit of the first sensing connection line 235a or the second sensing connection line 235b.

Rereferring to FIG. 9, FIG. 10, FIG. 13, and FIG. 14, the light shielding layer LS may be disposed on the substrate 210.

The data lines DL1 to DL4, the power line EVDD, the sensing line VREF, and the cathode power line EVSS may be disposed on the same layer as the light shielding layer LS.

The buffer layer 225 may be disposed on the substrate 210 on which the light shielding layer LS, the data lines DL1 to DL4, the power line EVDD, the sensing line VREF, and the cathode power line EVSS are disposed.

The semiconductor layer of the driving transistor DR may be disposed on the buffer layer 225.

The semiconductor layer ST_A of the sensing transistor ST and the semiconductor layer SW_A of the switching transistor SW may be disposed on the same layer as the semiconductor layer of the driving transistor DR.

For example, the semiconductor layer ST_A of the sensing transistor ST may extend toward the second repair part RP2 and constitute the first sensing connection line 235a and the second sensing connection line 235b.

For example, the first sensing connection line 235a and the second sensing connection line 235b may be electrically connected to the sensing line VREF through the sensing line contact hole CH_5. Also, the first sensing connection line 235a and the second sensing connection line 235b may be connected to each other. However, the present disclosure is not limited thereto.

For example, the sensing line VREF may be connected to the first sub-pixel SPn1 and the third sub-pixel SPn3 through the first sensing connection line 235a. Also, the sensing line VREF may be connected to the second sub-pixel SPn2 and the fourth sub-pixel SPn4 through the second sensing connection line 235b.

Further, the first sensing connection line 235a and the second sensing connection line 235b may be disposed on a semiconductor layer. Furthermore, the first sensing connection line 235a and the second sensing connection line 235b disposed on the semiconductor layer may be made of a transparent material.

For example, the semiconductor layers ST_A and SW_A, the first sensing connection line 235a, and the second sensing connection line 235b may be made of a silicon semiconductor or an oxide semiconductor. The silicon semiconductor may include amorphous silicon or polycrystalline silicon.

Also, the first sensing connection line 235a and the second sensing connection line 235b may be doped with impurities to become conductive. However, the present disclosure is not limited thereto.

Then, the interlayer insulating film 245 may be disposed on the semiconductor layers ST_A and SW_A, the first sensing connection line 235a, and the second sensing connection line 235b.

The passivation film 260 may be disposed on the interlayer insulating film 245.

The overcoating layer 265 may be disposed on the passivation film 260.

The organic light emitting diode OLED may be disposed on the overcoating layer 265.

More specifically, the first electrode ANO may be disposed on the overcoating layer 265.

The first electrode ANO may include the first anode ANO1 and the second anode ANO2. The first anode ANO1 and the second anode ANO2 are provided in each of the first to fourth sub-pixels SPn1 to SPn4. The first anode ANO1 and the second anode ANO2 may also be disposed on the first sensing connection line 235a and the second sensing connection line 235b so as to overlap the first sensing connection line 235a and the second sensing connection line 235b.

The bank layer 280 defining the first to fourth sub-pixels SPn1 to SPn4 may be disposed on the substrate 210 including the first electrode ANO of the organic light emitting diode OLED.

As described above, in the second embodiment of the present disclosure, the second repair part RP2 may be disposed in an area where each of the first sensing connection line 235a and the second sensing connection line 235b connected to the sensing line VREF is branched to the first to fourth sub-pixels SPn1 to SPn4.

When one of the emission areas EMA1 and EMA2 of the sub-pixels SPn1 to SPn4 malfunctions due to a short circuit of the first sensing connection line 235a or the second sensing connection line 235b, which may occur during the process, the second repair part RP2 may short-circuit (CL) the first sensing connection line 235a or the second sensing connection line 235b to short-circuit the first to fourth sub-pixels SPn1 to SPn4.

For example, in the second embodiment of the present disclosure, a portion of the first sensing connection line 235a or a portion of the second sensing connection line 235b may be electrically short-circuited (CL) by irradiating a laser from below the substrate 210. As described above, the electrical short circuit (CL) refers to making the first sensing connection line 235a or the second sensing connection line 235b non-conductive by irradiating the first sensing connection line 235a or the second sensing connection line 235b with a specific laser and increasing a resistance of the first sensing connection line 235a or the second sensing connection line 235b made of an oxide semiconductor.

For example, a laser having a wavelength of 256 nm may be used. However, the present disclosure is not limited thereto.

Herein, for example, if the second emission area EMA2 of the first sub-pixel SPn1 or the second emission area EMA2 of the third sub-pixel SPn3 is darkened, a portion of the first sensing connection line 235a may be short-circuited (CL). Also, if the first emission area EMA1 of the second sub-pixel SPn2 or the first emission area EMA1 of the fourth sub-pixel SPn4 is darkened, a portion of the second sensing connection line 235b may be short-circuited (CL).

As described above, in the second embodiment of the present disclosure, the second repair part RP2 is provided. Thus, when some emission areas EMA1 and EMA2 of some of the first to fourth sub-pixels SPn1 to SPn4 malfunction, only the malfunctioning emission areas EMA1 and EMA2 can be darkened.

Also, in the second embodiment of the present disclosure, a laser is irradiated from below the substrate 210. Thus, the first anode ANO1 and the second anode ANO2 of the metal layer can be disposed on the first sensing connection line 235a and the second sensing connection line 235b to be repaired. Therefore, an aperture ratio can be increased in proportion to the sizes of the first anode ANO1 and the second anode ANO2. For example, in the second embodiment of the present disclosure, the repair area is used as an opening. Therefore, it can be seen that an aperture ratio is increased by about 0.5% compared to the first embodiment.

The embodiments of the present disclosure can also be described as follows:

According to one or more embodiments of the present disclosure, there is provided a transparent display device. The transparent display device includes a substrate in which a plurality of sub-pixels including a transmission area and an emission area may be defined, a driving transistor disposed in the emission area, an organic light emitting diode connected to the driving transistor and an anode connection line extending from a semiconductor layer of the driving transistor to the transmission area and connected to an anode of the organic light emitting diode.

A data line, a sensing line, a power line, and a gate line may intersect one another to define the plurality of sub-pixels, and the sub-pixel may further include at least one of a switching transistor, a sensing transistor, and a capacitor.

The emission area may include a first emission area overlapping the driving transistor and a second emission area overlapping the switching transistor and the sensing transistor.

The anode may include a first anode disposed in the first emission area and a second anode disposed in the second emission area, and the anode connection line may include a first anode connection line and a second anode connection line connected to the first anode and the second anode, respectively.

The first anode and the second anode may extend to the transmission area, and each of the first anode connection line and the second anode connection line may be connected to a drain electrode of the driving transistor through a contact hole, and the first anode and the second anode extending to the transmission area may be integrally connected to each other through the first anode connection line and the second anode connection line to constitute a first repair part.

In the first repair part, the first anode connection line and the second anode connection line may be electrically connected to the first anode and the second anode, respectively, through an anode contact hole.

The anode connection line may be made of an oxide semiconductor.

The anode connection line may become conductive by doping an oxide semiconductor with impurities.

The first repair part partially may overlap the power line.

In case the first emission area or the second emission area may be darkened, the first anode connection line or the second anode connection line may become non-conductive by irradiating a portion of the first anode connection line or the second anode connection line with a laser from below the substrate.

The first anode and the second anode may be disposed on the first anode connection line and the second anode connection line to overlap the first anode connection line and the second anode connection line, respectively.

The transparent display device may further comprise a sensing connection line extending from a semiconductor layer of the sensing transistor.

The plurality of sub-pixels may include a first sub-pixel, a second sub-pixel, a third sub-pixel, and a fourth sub-pixel, and the sensing connection line may include a first sensing connection line connected to the first sub-pixel and the third sub-pixel and a second sensing connection line connected to the second sub-pixel and the fourth sub-pixel.

Each of the first sensing connection line and the second sensing connection line may be electrically connected to the sensing line through a sensing line contact hole.

The first sensing connection line and the second sensing connection line may be connected to each other.

The first sensing connection line and the second sensing connection line may be made of an oxide semiconductor.

The first sensing connection line and the second sensing connection line may become conductive by doping an oxide semiconductor with impurities.

In case the first emission area or the second emission area may be darkened, the first sensing connection line or the second sensing connection line may become non-conductive by irradiating a portion of the first sensing connection line or the second sensing connection line with a laser from below the substrate.

The first anode and the second anode may be disposed on the first sensing connection line and the second sensing connection line to overlap the first sensing connection line and the second sensing connection line, respectively.

The first sensing connection line may be disposed in the first sub-pixel and the third sub-pixel, and the second sensing connection line may be disposed in the second sub-pixel and the fourth sub-pixel.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts in the equivalent scope of the present disclosure should be construed as falling within the scope of the present disclosure.

What is claimed is:

1. A transparent display device, comprising:
a substrate with a plurality of sub-pixels on the substrate, the substrate including a transmission area and an emission area;
a driving transistor in the emission area, the driving transistor including a semiconductor layer;
an organic light emitting diode connected to the driving transistor, the organic light emitting diode including an anode; and
an anode connection line extending from the semiconductor layer of the driving transistor to the transmission area, the anode connection line connected to the anode of the organic light emitting diode.

2. The transparent display device of claim 1, wherein:
a data line, a sensing line, a power line, and a gate line intersect one another to define the plurality of sub-pixels; and
a sub-pixel of the plurality of sub-pixels includes at least one of a switching transistor, a sensing transistor, and a capacitor.

3. The transparent display device of claim 2, wherein the emission area includes a first emission area overlapping the driving transistor and a second emission area overlapping the switching transistor and the sensing transistor.

4. The transparent display device of claim 3, wherein:
the anode includes a first anode in the first emission area and a second anode in the second emission area; and
the anode connection line includes a first anode connection line connected to the first anode and a second anode connection line connected to the second anode.

5. The transparent display device of claim 4, wherein:
the first anode and the second anode extend to the transmission area;
each of the first anode connection line and the second anode connection line is connected to a drain electrode of the driving transistor through a contact hole; and
the first anode and the second anode extending to the transmission area are integrally connected to each other through the first anode connection line and the second anode connection line and form a first repair part.

6. The transparent display device of claim 5, wherein, in the first repair part, the first anode connection line is electrically connected to the first anode through an anode contact hole and the second anode connection line is electrically connected to the second anode through the anode contact hole.

7. The transparent display device of claim 1, wherein the anode connection line includes an oxide semiconductor.

8. The transparent display device of claim 1, wherein the anode connection line includes an oxide semiconductor doped with impurities, and the anode connection line is conductive.

9. The transparent display device of claim 5, wherein the first repair part partially overlaps the power line.

10. The transparent display device of claim 4, wherein the first anode connection line or the second anode connection line is non-conductive as a result of irradiating a portion of the first anode connection line or a portion of the second anode connection line with a laser from below the substrate while the first emission area or the second emission area is being darkened.

11. The transparent display device of claim 4, wherein:
the first anode is on the first anode connection line and overlapping the first anode connection line; and
the second anode is on the second anode connection line and overlapping the second anode connection line.

12. The transparent display device of claim 4, further comprising:
a sensing connection line extending from a semiconductor layer of the sensing transistor.

13. The transparent display device of claim 12, wherein:
the plurality of sub-pixels includes a first sub-pixel, a second sub-pixel, a third sub-pixel, and a fourth sub-pixel; and
the sensing connection line includes a first sensing connection line connected to the first sub-pixel and the third sub-pixel and a second sensing connection line connected to the second sub-pixel and the fourth sub-pixel.

14. The transparent display device of claim 13, wherein each of the first sensing connection line and the second sensing connection line is electrically connected to the sensing line through a sensing line contact hole.

15. The transparent display device of claim 13, wherein the first sensing connection line and the second sensing connection line are connected to each other.

16. The transparent display device of claim 13, wherein the first sensing connection line and the second sensing connection line include an oxide semiconductor.

17. The transparent display device of claim 13, wherein the first sensing connection line and the second sensing connection line include an oxide semiconductor doped with impurities, and the first connection line and the second connections line are conductive.

18. The transparent display device of claim 13, wherein the first sensing connection line or the second sensing connection line is non-conductive as a result of irradiating a portion of the first sensing connection line or a portion of the second sensing connection line with a laser from below the substrate while the first emission area or the second emission area is being darkened.

19. The transparent display device of claim 13, wherein:
the first anode is on the first sensing connection line and overlapping the first sensing connection line; and
the second anode is on the second sensing connection line and overlapping the second sensing connection line.

20. The transparent display device of claim 13, wherein:
the first sensing connection line is in the first sub-pixel and the third sub-pixel; and
the second sensing connection line is in the second sub-pixel and the fourth sub-pixel.

21. The transparent display device of claim 3, wherein the anode includes a first anode in the first emission area and a second anode in the second emission area, and
wherein the anode connection line is branched in the transmission area toward the first anode and the second anode.
